(19) United States
(12) Patent Application Publication
(10) Pub. No.: US 2012/0280352 A1
(43) Pub. Date: Nov. 8, 2012

(54) SEMICONDUCTOR STRUCTURE WITH HEAT SPREADER AND METHOD OF ITS MANUFACTURE

(75) Inventors: Eran Hochstadter, Kadima (IL); John F. Roulston, Edinburgh (GB)

(73) Assignee: NOVATRANS GROUP SA, Gorgier (CH)

(21) Appl. No.: 13/520,678

(22) PCT Filed: Jan. 12, 2011
(86) PCT No.: PCT/IL11/00036

§ 371 Date: Jul. 5, 2012

Related U.S. Application Data
(60) Provisional application No. 61/294,242, filed on Jan. 12, 2010.

(51) Int. Cl. H01L 31/024; H01L 31/18

(52) U.S. Cl. 257/466; 438/64; 257/E31.131; 257/E31.032

(57) ABSTRACT

A semiconductor structure is provided and a method for manufacturing said structure. The semiconductor structure includes a thin film semiconductor having an active region and placed on a diamond substrate. The thin film semiconductor is preferably directly bonded to the diamond layer, or may be adhered thereto by a dielectric adhesion.

### FIELD AND BACKGROUND OF THE INVENTION

This invention relates to a semiconductor structure utilizing a heat spreader and a method of its manufacture. In particular, the invention is useful for photoconductor structures and power devices. Photoconductors, being a semiconductor based material whose resistance changes in response to incident light intensity, are useful in various applications, including inter alia phototransistors, photoconductive antennas, light meters, etc.

The invention is particularly useful for high-frequency (sub-millimeter and THz frequency range) radiation emitting devices. Such devices typically utilize epitaxially grown compound semiconductor material (III-V). For example, low temperature growth of GaAs material permits high carrier mobility and very short carrier recombination time allowing photoconductors formed of such material to respond to THz modulation such as can be created by beating two CW lasers or by single short pulse lasers.

WO 2009/146561 describes terahertz transmitter and receiver utilizing a photoconductive antenna, which is formed by a substrate, a heat spreader epilayer, a photoconductor layer, and electrodes on top thereof. The photoconductive material used for making the photoconductor layer and the substrate may be GaAs.

It is a common goal in the field of power packages to dissipate heat from active components economically and efficiently. To this end, isolation materials are used, which are to meet such requirements as exhibiting high dielectric breakdown voltage, high thermal conductivity, and extremely low leakage current. Common practice today is using various isolating films in between the active power device and the package. This is illustrated schematically in FIG. 1A. Here, Al₂O₃ (aluminum oxide) or AlN (aluminum nitride) is used as an isolating material. An example of a structure similar to that of FIG. 1A but utilizing a diamond as a bulk substrate for an active semiconductor device is shown schematically in FIG. 1B. Some advantages in using diamond substrate (FIG. 1B) as compared to Al₂O₃ or AlN are described in the following publication: “Diamond films as thermal conductors and electrical insulators applied to semiconductor power modules”, B. Fiegi et al., Diamond and Related materials, 3 (1994), pp. 658-662.

Some techniques for creation of a semiconductor on diamond devices are described for example in U.S. Pat. No. 7,498,191. According to this technique, a base layer may be deposited onto a lattice-orienting Si substrate such that the base layer lattice is substantially oriented by the Si substrate, a semiconductor layer is deposited onto the base layer such that the semiconductor layer lattice is substantially oriented with respect to the base layer lattice, and a layer of diamond is deposited onto the semiconductor layer. Diamond layer may be formed separately from the semiconductor layer and coupled thereto using an adhesive or bonding material (an ultra thin layer of bonding material). Prior to bonding, corresponding adjoining surfaces may be polished or prepared to have a comparable surface roughness. The surface roughness will depend on the intended final device. Subsequently, an ultra thin layer of bonding material may be produced by forming a layer of bonding material on either of the surfaces to be joined and then pressing the two surfaces together in order to reduce the bonding layer thickness to less than about 1 micron and preferably less than about 10 nanometers (i.e. only a few molecules thick). The bonding material may comprise an organic binder such as an epoxy or may be a reactive metal such as Ti, Si, Zr, Cr, Mo, W, Mn, or mixtures thereof. In the case of a reactive metal, the metal may be sputtered on either surface and then pressed against the other surface under heat and vacuum conditions. Alternatively, a diamond layer may be brazed to the semiconductor layer.

U.S. Pat. No. 6,461,889 describes a method of fabricating semiconductor device with diamond substrate, aimed at decreasing the thermal resistance of the semiconductor device. According to this technique, first, a semiconductor base layer is formed over a main surface of a semiconductor substrate. Then, the semiconductor base layer on which the at least one device structure has been formed is separated from the main surface of the semiconductor substrate. Further, the semiconductor base layer on which the at least one device structure has been formed and separated from the main, surface of the semiconductor substrate is attached onto a main surface of a diamond substrate. Finally, the semiconductor base layer thus attached is fixed to the main surface of the diamond substrate. The semiconductor base layer is preferably formed over the main surface of the semiconductor substrate through an intervening sacrificial layer. Also, the semiconductor base layer is separated from the main surface of the semiconductor substrate by removing the sacrificial layer. The semiconductor base layer is fixed to the main surface of the diamond substrate by physical absorption or an intermolecular force such as a van der Waals force.

### GENERAL DESCRIPTION

It is often a case, particularly with a high frequency emitter, that a semiconductor emitter layer or film is very thin, i.e. has a small dimension in the vertical direction, transverse to the current flow. This is certainly the case for high-frequency photo-conductors since the active region is fundamentally limited by the opacity of the material and the small penetration of laser light into the material. Typically, the active region is only 1-2 microns thickness. Such an ultra thin film semiconductor needs to be supported by a substrate material providing mechanical rigidity.

Considering the structure shown in FIG. 1A, it suffers from the fact that the active power device is actually built on a semiconductor bulk substrate which has poor thermal conductivity and compromised electrical insulation properties. The power device is electrically coupled initially to the bulk, i.e. poor thermal conductor. Although the bulk may be thin, it still represents fairly high thermal resistor. Such a structure in most cases would require additional external heat dissipation assembly like a heat sink. It is recognized that, in most instances, placing a semiconductor photoconductor (e.g. GaAs, or a similar semiconducting material using elements of Periodic Groups III and V) on a diamond substrate would be highly advantageous. This would limit temperature rises to a few degrees K. FIG. 1E illustrates simulation results showing how temperature of a silicon chip depends of the thickness of a silicon substrate.

For example, GaAs has a thermal conductivity around 40 W/m/K while diamond is 50 times better. Diamond has the thermal conductivity by far while not scarifying any of the electrical isolation properties.

In the field of power transistors, it is known to perform thermal management of the power transistors where the active transistor layer (semiconductor layer) is liberated by a “lift-off” process and metallically bonded to a heat-spreading substrate. Typically, a poly-crystalline diamond substrate is used, in order to increase the transistor power. In such devices, electrical energy is coupled from the active semiconductor by metallic conductors; there is no radiative mechanism involved. Thus, the adherence of the semiconductor film to a diamond substrate can be facilitated by metallic layers that bind to both GaAs and diamond. Such a structure is illustrated in a self-explanatory manner in FIG. 1C. Each of the GaAs fingers acts as a centre of THz radiation.

The diamond substrate may first be seeded with Cr (say 5 nm), which adheres strongly, and on top of this 10 nm Pd provides a surface that has an affinity for GaAs. The metallic layer is so thin that the thermal resistance it imposes is low and has little effect on the heat transfer to the diamond heat-spreading substrate.

The above described techniques however are inappropriate for photoconductors, where efficiency of the radiating structure is to be maintained. Indeed, in transistors with a conductive energy path the presence of a Cr/Pd metallic bonding layer might pose no disadvantage. However, for a radiative structure the presence of a metallic sheet would seriously compromise the antenna function due to current flow in the sheet radiating in opposite phase to the primary radiator. It would also be necessary to interrupt the metallic layer to avoid short-circuiting the active GaAs fingers, and this would imply the need for precision alignment which is also highly undesirable, given the fragile nature of the active film.

Another known approach is to place a semiconductor film directly on a glass window. This is illustrated in FIG. 1D. As the film is not exactly flat, it contacts the glass substrate at discrete points, and there is no bonded interface to the substrate so that intimate thermal contact is not achieved. The glass window is good for THz transmission, but is ineffective as a heat-spreading agent.

The present invention provides for novel semiconductor structures (e.g. using a photoconductor) in which a thin-film (a few micrometers thick, e.g. 1-2 micrometers) semiconductor (photoconductor) is placed on top of a diamond support.

According to some embodiments of the invention, a relatively thin diamond layer (typically in the range from a few tens to a few hundreds of microns, e.g. 100 microns) is directly attached to an active thin-film semiconductor (e.g. epitaxy layer; e.g. photoconductor). This can be achieved by first providing a structure formed by said thin-film semiconductor on a parent substrate (this could be GaAs, LTGaAs, INP, silicon, or SiGe, or any combination of such materials) being spaced from the parent substrate by an insulator layer (such as AlAs). Then, the diamond layer is directly bonded to the other side of the thin-film semiconductor (by bonding between the atoms of diamond and the semiconductor material). Then, a structure formed by the thin-film semiconductor with the diamond bonded thereto is separated from the parent substrate. For example, in the case of a high-frequency photo-resistor it is desirable to separate the thin active layer (film) from a parent substrate to avoid radiation losses in penetrating the substrate. The separation can be performed using a standard “lift-off” process where said insulator layer between the semiconductor and the parent substrate serves as a “stop-etch”. This process is generally known and is described for example in the following article and references included therein: Arbet-Engels V. et al., “Flexible, Thin-Film, GaAs Hetero junction Bipolar Transistors Mounted on Natural Diamond Substrates”, Solid-State Electronics, vol. 38, no. 11, 1995, pp. 1972-1974, UK.

In the case of THz photoconductors, this lift-off technique is highly desirable, motivated by the advantage gained in avoiding the severe parent substrate attenuation of the emitted THz radiation.

The direct bonding of the diamond layer to the thin film semiconductor is carried out at relatively low temperature, preferably less than 200 C. Use of higher temperatures might result in degradation of such properties of the semiconductor as electron mobility and recombination time. One of the options to reach the required low temperature is by using plasma in the bonding process. In this process, the diamond and the active semiconductor are subjected to a plasma treatment prior to bringing them into contact for bonding. The surface activation allows the process temperature to be in a range from room temperature to maximum of about 400° C.

In some other embodiments, the thin-film photoconductor is adhered to the diamond support using a dielectric adhesion, such as photoresist. The present invention provides a method of attachment (bonding) of a thin-film semiconductor to the substrate in a manner ensuring an intimate thermal contact in the bonding process. The invention utilizes an adhesive, which is non-conductive and insignificant in dielectric effect. The adhesive is preferably extremely thin, e.g. mono-molecular layer, affording excellent thermal conductivity resistance. A suitable adhesive is a very thin layer of photoresist, or other dielectric material(s). This could be convenient in situations where the performance level of the mono-molecular layer is unnecessary. The adhesive/bonding material is preferably selected to have a refractive index matching a refractive index difference between the diamond and the active semiconductor layer so as to meet a requirement for maximal transmission of input electromagnetic radiation (e.g. of a predetermined wavelength range) through the heat spreader (diamond) and said adhesive material towards the active photoconductor film.

In order to ensure uniform area contact between the semiconductor film (GaAs in particular) and the substrate (diamond), a jig may be used to apply even atmospheric pressure.

The active film may be separated from its parent substrate either before or after bonding to the heat-spreading substrate. In the case where the heat-spreading substrate is bonded before separation of the film, a selective etch may be used. In this case, a vacuum jig may also be a convenient way to apply even pressure to facilitate bonding.

The present invention thus provides for a simple and effective solution for a photoconductor structure that may be used with strong laser light sources and radiate efficiently.

Thus, according to one broad aspect of the invention, there is provided a semiconductor structure consisting of a thin film semiconductor having an active region and a heat spreading diamond layer directly bonded to said thin film semiconductor.

As indicated above, in some embodiments of the invention, the semiconductor is photoconductor and is a thin film of GaAs, or a similar compound semiconductor material using elements of Periodic Groups III and V.

The thickness of the semiconductor (photoconductor) may a few micrometers, e.g. about 1000-2000 nanometers.

According to another broad aspect of the invention there is provided a method for manufacturing a semiconductor structure, the method comprising: bonding a semiconductor film by its one surface to a parent substrate using an insulator material layer; directly bonding a diamond layer to an opposite surface of the semiconductor film; applying a lift off process to said insulator layer to thereby separate said parent substrate from the semiconductor film.

According to yet another broad aspect, there is provided a semiconductor structure comprising a thin film semiconductor having an active region and placed on a diamond substrate, said thin film semiconductor being adhered to the diamond substrate by a dielectric adhesion.

The dielectric adhesion may be in the form of a monolayer of appropriate dielectric material. The dielectric adhesion may comprise a polymer film, and may for example be a photoresist layer.

For some applications (e.g. back illumination of the photoconductor), the diamond substrate and the dielectric adhesion are optically transparent for a predetermined wavelength range.

According to yet further broad aspect of the invention, there is provided a method for manufacturing a semiconductor structure, the method comprising: providing a diamond substrate; applying a dielectric adhesion material to a surface of said diamond substrate, placing a semiconductor film above said dielectric adhesion material, and creating a pressure difference at opposite surfaces of the film such that pressure from outside surface is much higher thereby adhering the film to the dielectric material.

### BRIEF DESCRIPTION OF THE DRAWINGS

In order to understand the invention and to see how it may be carried out in practice, embodiments will now be described, by way of non-limiting example only, with reference to the accompanying drawings, in which:

FIGS. 1A to 1D illustrate four examples, respectively, of a semiconductor on substrate structure configured according to conventional approaches;

FIG. 1E illustrates simulation results for the temperature dependence of a silicon chip on the thickness of a silicon substrate;

FIG. 2A schematically illustrates the layout of a semiconductor structure according to an embodiment of the invention;

FIG. 2B exemplifies a method of the invention for attaching the semiconductor film to the heat spreading substrate in the semiconductor structure of FIG. 2A, in a manner ensuring uniform area contact between the film and the substrate;

FIG. 3A schematically illustrates the layout of a semiconductor structure according to another embodiment of the invention;

FIGS. 3B to 3D exemplify a method of manufacturing the semiconductor structure of FIG. 3A.

### DETAILED DESCRIPTION OF EMBODIMENTS

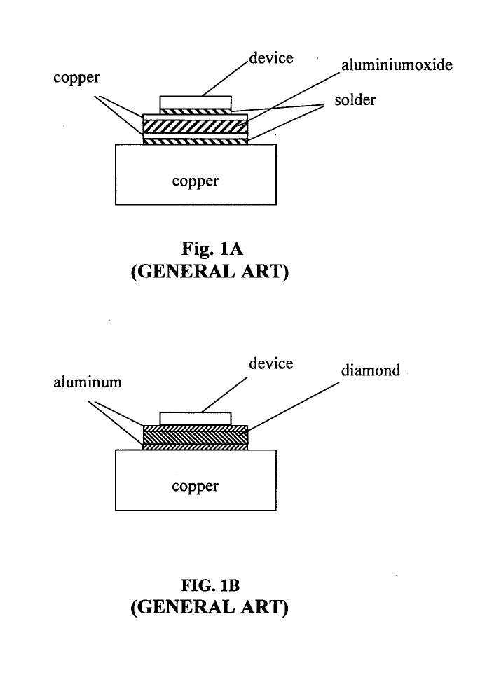

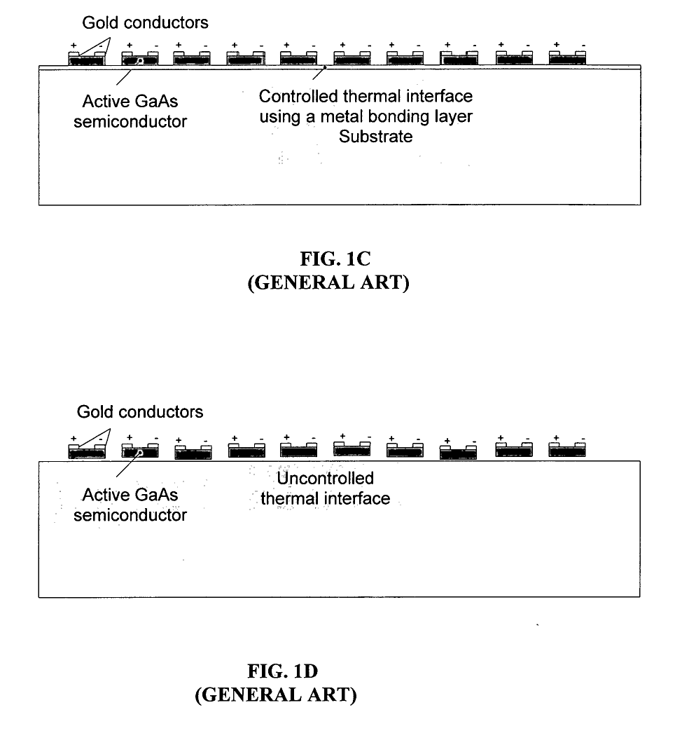

FIGS. 1A to 1D illustrate the principles of four known approaches for manufacture of a semiconductor on substrate structure. In FIG. 1A, an Al₂O₃ (aluminum oxide) or AlN (aluminum nitride) isolating film is used between an active power device and a substrate. In FIG. 1B, a diamond is used as a bulk substrate for an active semiconductor device. In FIG. 1C, the semiconductor layer is bonded to the substrate by a metallic spacer. In FIG. 1D, the semiconductor is directly placed on the glass window. FIG. 1E shows the simulation results for the temperature dependence of a silicon chip on the thickness of a silicon substrate.

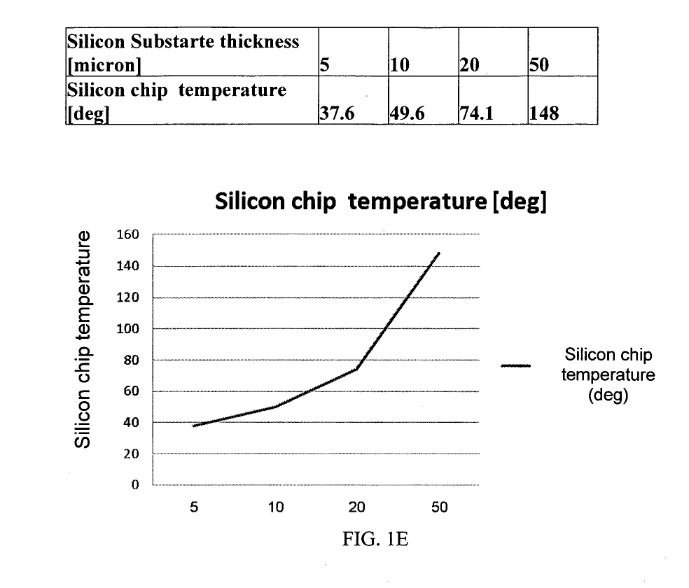

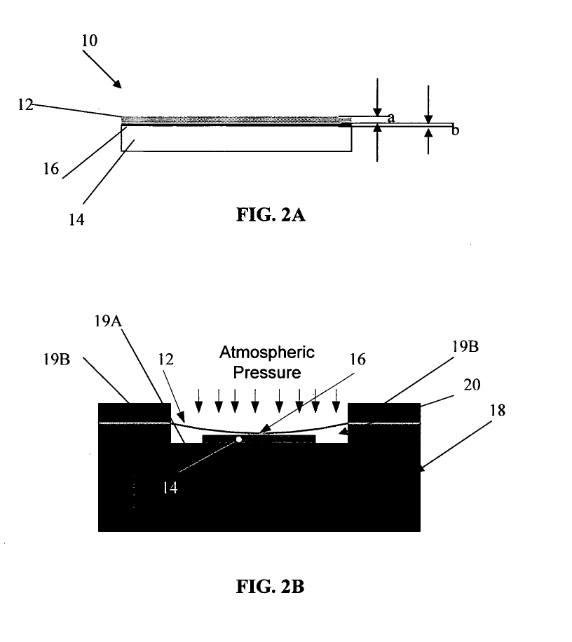

Referring to FIG. 2A, there is illustrated a semiconductor structure 10 configured according to the invention. More specifically, the present invention is used for manufacture of a high-frequency (in THz spectral range) photoemitter, and will therefore described below with respect to this specific application. It should however be understood that the invention is not limited to this specific embodiment, and the principles of the invention can be used with various semiconductor materials and suitable dielectric adhesions.

The structure 10 includes a photoconductor layer 12 (constituting a semiconductor) supported on a diamond substrate 14. The photoconductor 12 is in the form of a thin film semiconductor (typically GaAs) having a thickness a of about a few micrometers (e.g. 1000-2000 nanometers). The substrate 14 is configured to perform heat spreading from the semiconductor film 12 when in operation. Considering photoconductor-based applications, the heat spreading substrate is preferably appropriately optically transparent to enable illumination of the active region (active device) on the film 12 through the substrate.

The diamond substrate 14 preferably has an appropriate thickness. A convenient thickness is about 100-200 microns, e.g. 130 microns, which is mechanically robust, economic to create, and effective in heat conduction. Diamond substrates thinner than 30 microns, such as may be achieved by deposition of diamond film, might be ineffective in heat transmission because of the phonon interaction distance in diamond which is around 30 microns.

The semiconductor film 12 is attached to the substrate 14 by an adhesive layer 16. The adhesive layer is a dielectric material layer, e.g. polymer, e.g. photoresist, or thermally conductive adhesives for high vacuum environments such as Master Bond EP2xxx or EP3XXX adhesive family. The dielectric material layer is preferably very thin, e.g. thickness b of about 15 nanometers.

Generally, considering back illumination of the photoconductor 12 through the optically transparent substrate 14, the dielectric adhesion is also optically transparent for a wavelength range used for the photoconductor illumination. This may be achieved by appropriate material composition of the dielectric adhesion and/or making it sufficiently thin, i.e. of a thickness smaller than the wavelength used.

As indicated above, the adhesion between the semiconductor layer 12 and the diamond substrate 14 should preferably be such as to ensure uniform area contact along an interface between them, while not affecting the operation of the very thin optically active region in the semiconductor. Generally, this may be achieved using selective etch. More specifically, the diamond heat spreader 14 may be bonded to the semiconductor film 12, while the semiconductor film 12 is attached to a parent substrate, and then, after bonding, the film 12 is separated from the parent substrate by selective etch of a bonding material therebetween.

The process of adhering a diamond layer to the active semiconductor (e.g. GaAs) may for example be as follows: A GaAs chip is bonded to a piece of diamond using a very small drop of UV adhesive (e.g. photoresist). The chip is pushed against the diamond with a special jig to maintain uniform pressure to spread liquid glue, and then a piece of adhesive tape is applied to hold the chip in place during the UV exposure. The glue layer is exposed to UV light (e.g. 365 nm) through the transparent diamond substrate, for about 2 minutes, using a Karl Suss MA 8 mask aligner or the like, and a 100 mm diameter Fresnel lens to focus the light onto the chip at higher intensity. The edges of the chip are coated by the glue which would mask any attempt to etch out the sacrificial layer. Since the glue is a polymer, it was treated with an oxygen plasma in a barrel asher for 1 hour. This had a dramatic effect: the bulk of the excess glue was removed, leaving a fillet of material at the interface. The sample was soaked in a 10% HF solution for 21 hours without any problems and the sacrificial layer was etched, leaving the adhesive layer on the diamond.

Reference is made to FIG. 2B showing a system suitable for carrying the above-described method for achieving appropriate adhesion between a semiconductor film 12 and a heat spreading diamond substrate 14. As shown, a jig assembly 18 is used. The latter has a support surface 19A on which the substrate 14 is placed with an adhesive material 16 thereon, and side portions 19B for holding the film 12 at opposite ends thereof such that a free portion of the film 12 is aligned with the substrate 14. This jig 18 is configured to enable creation of a pressure difference within a cavity 20 formed between the free portion of the film 12 and the surface portion 19 and outside said cavity. For example, the cavity 20 is kept under vacuum conditions, and high (e.g. atmospheric) pressure is applied to the outer surface of the film 12 from outside the cavity. It should be noted that the geometry of the arrangement (i.e. a distance between the side portions 19B and their height) is appropriately adjusted to reduce the curvature of the free portion of the film 12 at a contact region with the adhesion material 16, thereby facilitating the adhesion by application of pressure.

It should be understood that in the semiconductor structure of the present invention the active semiconductor film 12 might be in a certain misalignment with the heat-spreading substrate 14 because there is no need for critical alignment between them. Also, with the present invention, the interdigitated structure of an array formation does not require sophisticated efforts to avoid metallic short-circuits across the fingers.

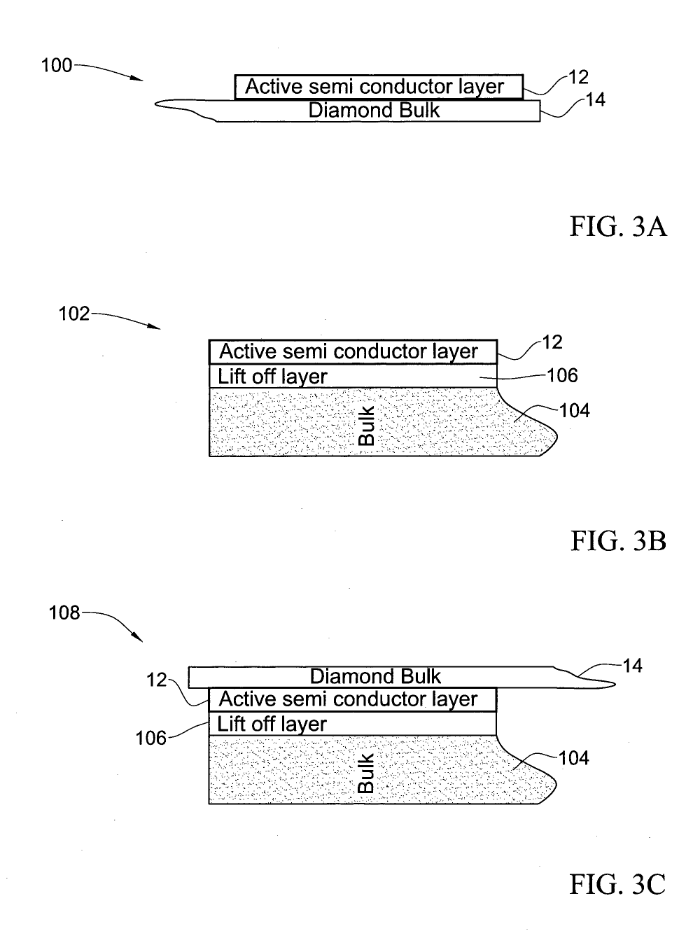

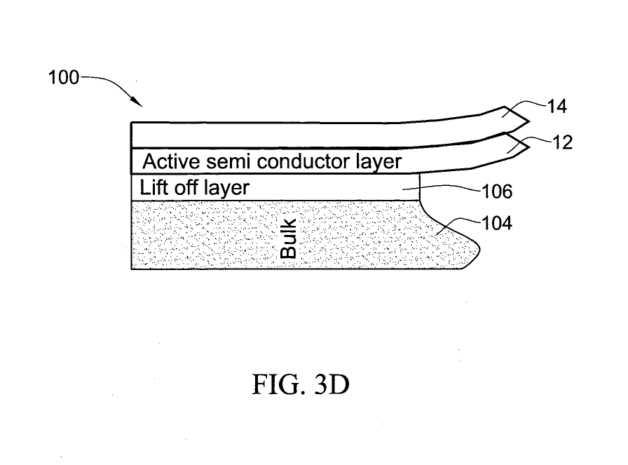

Reference is made to FIGS. 3A to 3D illustrating another embodiment of the invention. To facilitate understanding the same reference numerals are used for identifying common functional components in all the examples described in the present application. FIG. 3A shows a semiconductor structure 100 of the invention formed by an active thin-film semiconductor 12 located directly on a heat spreader diamond layer 14. The diamond layer 14 may have a thickness of about 100-200 microns (generally from a few tens to a few hundreds of microns). The thickness of the active layer 12 may be of about a few microns. Considering active photoconductor layer 12 (e.g. for use in photomixer-based applications), the thickness is about 2-3 microns; in power devices the active semiconductor might be thicker.

FIGS. 3B to 3D exemplify the successive stages in a method of manufacturing the structure 100. As shown in FIG. 3B, initially, a structure 102 is prepared, being formed by the active thin-film semiconductor 12 which is by its one surface bonded to a parent substrate 104 by a bonding layer 106. Then, the diamond layer 14 is directly bonded to the opposite surface of the thin-film semiconductor 12 resulting in an intermediate structure 108 (FIG. 3C). Thereafter, as illustrated in FIG. 3D, a list-off procedure is applied to structure 108 where the bonding layer 106 serves as “stop etch” layer being removed while separating the parent substrate 104 from the semiconductor film 12.

1. A semiconductor structure consisting of a thin film semiconductor having an active region, and a heat spreading diamond layer directly bonded to said thin film semiconductor.

2. A semiconductor structure according to claim 1, wherein said thin film semiconductor is a photoconductor.

3. A semiconductor structure according to claim 1, wherein said thin film semiconductor comprises GaAs.

4. A semiconductor structure according to claim 1, wherein a thickness of said thin film semiconductor is about a few micrometers.

5. A semiconductor structure according to claim 1, wherein a thickness of said thin film semiconductor is about 1000-2000 nanometers.

6. A method for manufacturing a semiconductor structure of claim 1, the method comprising: bonding a semiconductor thin film by its one surface to a parent substrate using a boding material layer; directly bonding a heat spreader layer to an opposite surface of the semiconductor film; applying a lift off process to separate said parent substrate from the semiconductor film.

7. A semiconductor structure comprising a thin film semiconductor having an active region and placed on a heat spreading diamond substrate, said thin film semiconductor being adhered to the diamond substrate by a dielectric adhesion.

8. A semiconductor structure according to claim 7, wherein said thin film semiconductor is a photoconductor.

9. A semiconductor structure according to claim 7, wherein said thin film semiconductor comprises GaAs.

10. A semiconductor structure according to claim 7, wherein a thickness of said thin film semiconductor is about a few micrometers.

11. A semiconductor structure according to claim 7, wherein a thickness of said thin film semiconductor is about 1000-2000 nanometers.

12. A semiconductor structure according to claim 7, wherein said thin dielectric adhesion is a monolayer.

13. A semiconductor structure according to claim 7, wherein said dielectric adhesion comprises a polymer film.

14. A semiconductor structure according to claim 7, wherein said thin dielectric adhesion comprises a photoresist layer.

15. A semiconductor structure according to claim 7, wherein said thin dielectric adhesion comprises a Thermally Conductive Adhesive.

16. A semiconductor structure according to claim 8, wherein the dielectric adhesion is optically transparent for a predetermined wavelength range.

17. A semiconductor structure comprising: a GaAs thin film photoconductor adhered to a diamond heat spreader substrate by a dielectric adhesion.

18. A method for manufacturing the semiconductor structure of claim 7, the method comprising: providing a heat spreader substrate; applying a dielectric adhesion material to a surface of said heat spreader substrate, placing a semiconductor film above said dielectric adhesion material, and creating a pressure difference at opposite surfaces of the film such that pressure from outside surface is much higher thereby adhering the film to the dielectric material.
